(19) United States
(12) Patent Application Publication
(10) Pub. No.: US 2024/0272204 A1
(43) Pub. Date: Aug. 15, 2024

(54) Current Measurement Device And Current Sensor

(71) Applicant: Alps Alpine Co., Ltd., Tokyo (JP)

(72) Inventors: Manabu TAMURA, Miyagi-ken (JP); Akira MIYAJI, Miyagi-ken (JP); Chiaki UEDA, Miyagi-ken (JP)

(21) Appl. No.: 18/536,477

(22) Filed: Dec. 12, 2023

(30) Foreign Application Priority Data
Feb. 9, 2023 (JP) 2023-018174

(51) Int. Cl. G01R 15/20; G01R 19/00

(52) U.S. Cl. CPC G01R 15/20; G01R 19/0092

(57) ABSTRACT

A current sensor has a chassis, a magnetism detection element, and a bus bar through which a current under measurement flows. The current sensor is mounted on a circuit board in a state in which the chassis is inserted into an opening formed in the circuit board with current paths provided on a mounting surface and the bus bar is connected to the current paths. The bus bar has an incorporation portion placed in the interior of the chassis as well as externally connected portions extending from both ends of the incorporation portion, one from each side, toward the outside of the chassis. The externally connected portions are positioned above the bottom surface of the chassis in the up-down direction. The incorporation portion has an underneath portion positioned below the externally connected portions in the up-down direction.

### CLAIM OF PRIORITY

This application claims benefit of Japanese Patent Application No. 2023-018174 filed on Feb. 9, 2023, which is hereby incorporated by reference.

### BACKGROUND OF THE INVENTION

### 1. Field of the Invention

The present invention relates to a current sensor and a current measurement device that detect a magnetic field generated when a current under measurement flows through a bus bar and measure the current value of the current under measurement from the detected magnetic field.

### 2. Description of the Related Art

In recent years, a current sensor and a current measurement device that are attached to any type of unit and measure a current under measurement that flows through the unit are used to control and monitor the unit. A known current sensor of this type uses a magneto-electric conversion element that senses a magnetic field generated by a flow of a current under measurement through a bus bar, which is a current path. Along with a shift toward downsizing and weight reduction of units eligible for being controlled or monitored such as driving inverters, a technology for mounting a current sensor on a circuit board has been proposed.

Japanese Unexamined Patent Application Publication No. 2020-106302 describes a current measurement device, which has a structure by which a low profile is possible, intended to suppress a rise in the temperatures of a bus bar and magnetism detection element and to facilitate heat dissipation. The current measurement device has a wiring board with current paths provided on a mounting surface as well as a current sensor having a main body portion and bus bars extending from the main body portion. The current measurement device measures a current flowing through the bus bars. With the current measurement device, the wiring board has an opening, the bus bars are electrically connected to the current paths, the main body portion is inserted into the opening, and the bottom surface of the main body portion is positioned below the mounting surface.

With the current measurement device in Japanese Unexamined Patent Application Publication No. 2020-106302, heat is efficiently dissipated from the bottom surface of the main body portion by a structure in which the bottom surface of the main body portion, inserted into the opening in the wiring board, of the current sensor is positioned below the mounting surface of the wiring board so that the bottom surface of the main body portion is exposed on the same side as the bottom surface, on which there is no large heat source, of the wiring board. Therefore, it becomes possible to suppress a rise in the temperature of the current sensor. However, the bus bar, which becomes a heat source, is routed not on the same side as the bottom surface of the wiring board but on the same side as the mounting surface opposite to the bottom surface. This is problematic in that the cooling efficiency of the bus bar is low.

### SUMMARY OF THE INVENTION

In view of the above situation, the present invention provides a current sensor and a current measurement that are structured so that a rise in the temperatures of the bus bar and current sensor is suppressed as a result of improving the cooling efficiency of the bus bar and that heat is easily dissipated even if temperature rises.

The present invention has the following structure as a means for solving the problem described above.

A current sensor has a chassis, a magnetism detection element, and a bus bar through which a current under measurement flows, the current sensor being mounted on a circuit board in a state in which the chassis is inserted into an opening formed in the circuit board with current paths being provided on a mounting surface and the bus bar is connected to the current paths. The bus bar has an incorporation portion placed in the interior of the chassis as well as externally connected portions extending from both ends of the incorporation portion, one from each side, toward the outside of the chassis. In a first direction, which is the normal direction of the circuit board, a side on which the mounting surface is positioned will be taken as an upper side; and a side opposite to the upper side will be taken as a lower side with respect to the center of the circuit board in the first direction. Then, the externally connected portions are positioned above the bottom surface of the chassis in the first direction, and the incorporation portion has an underneath portion positioned below the externally connected portions in the first direction.

Since the incorporation portion of the bus bar has the underneath portion positioned below the externally connected portions, heat of the bus bar can be efficiently dissipated from the lower surface of the circuit board, the temperature of the lower surface being lower than the temperature of the mounting surface, so the cooling efficiency of the current sensor is improved.

With the current sensor, the bottom surface of the chassis may be positioned below a back surface, which is the lower surface of the circuit board. With the current sensor, the underneath portion may have a portion positioned below the back surface, which is the lower surface of the circuit board.

In these structures, heat of the bus bar can be more efficiently dissipated from the underneath portion in the incorporation portion in the bus bar.

The underneath portion may have a bottom portion extending along the bottom surface of the chassis as well as linking portions that extend upward from both ends of the bottom portion, one from each side, and each of which is connected to the relevant externally connected portion.

Since the bottom portion is provided in the underneath portion, the bus bar can be cooled by efficiently dissipating heat of the bottom portion from the bottom surface of the chassis.

The magnetism detection element may be placed at a position, in the interior of the chassis, at which the magnetism detection element faces the bottom portion in the first direction.

The temperature of the bottom portion is less likely to rise when a current under measurement flows through the bus bar. Even if the temperature rises, heat can be quickly dissipated. Thus, when the magnetism detection element is placed at a position at which the magnetism detection element faces the bottom portion, the temperature of the magnetism detection element can be kept low and a drop in precision of the current sensor due to a rise in the temperature of the magnetism detection element can thereby be suppressed.

The magnetism detection element may be placed, in the interior of the chassis, below the externally connected portions in the first direction.

In this structure, the magnetism detection element can detect not only a magnetic field generated from the bottom portion of the bus bar but also a magnetic field generated from a perpendicular portion, so the strength of a signal magnetic field to be detected becomes large. Therefore, the signal-to-noise (S/N) ratio of the magnetism detection element is improved and measurement precision of the current sensor thereby becomes superior.

Since the magnetism detection element is placed on the same side as the back surface of the circuit board, the temperature of the back surface being relatively lower than the temperature of the mounting surface of the circuit board, the risk can be reduced that the magnetism detection element exceeds its durable temperature with the suppression of a temperature rise during usage.

The incorporation portion may have a thick portion, the thickness of which is greater than the thicknesses of other portions in the first direction, at a narrow portion, the width of which is smaller than the widths of the other portions when viewed from the first direction.

To improve frequency characteristics due to a skin effect, some bus bar has a narrow portion, the width of which is smaller than the widths of other portions, at a portion placed so as to face the magnetism detection element. When a bus bar has a narrow portion, if a thick portion, the thickness of which is greater than the thicknesses of the other portions, is provided at the narrow portion, the cross-sectional area of the bus bar at the narrow portion can be made substantially equal to the cross-sectional areas of portions other than the narrow portion. Thus, it is possible to suppress generated heat by suppressing the electric resistance at the narrow portion of the bus bar to a low level.

The thick portion may have a heat dissipating portion protruding downward beyond the externally connected portions.

When the heat dissipating portion protruding downward beyond the externally connected portions is provided at the thick portion of the narrow portion, the cooling efficiency of the thick portion is improved.

The current sensor may have a magnetic shield.

Since magnetic noise from the outside to the magnetism detection element can be suppressed by the magnetic shield, measurement precision of the current sensor is improved.

A current measurement device that has the current sensor described above and the circuit board with the current paths provided on the mounting surface.

In the structure having the underneath portion, heat of the bus bar can be efficiently dissipated from the same side as the back surface of the circuit board, the temperature of the back surface being lower than the temperature of the mounting surface, so the current measurement device has superior cooling efficiency.

According to the present invention, it is possible to provide a current sensor and a current measurement device that are structured so that a rise in the temperatures of the bus bar and current sensor is suppressed as a result of improving the cooling efficiency of the bus bar and that heat is easily dissipated even if temperature rises.

### BRIEF DESCRIPTION OF THE DRAWINGS

FIG. 1A is a sectional view schematically illustrating the structure of a current sensor according to a first embodiment;

FIG. 1B is a sectional view schematically illustrating the structure of a bus bar in FIG. 1A;

FIG. 1C is also a sectional view schematically illustrating the structure of the bus bar in FIG. 1A;

FIG. 2 is a plan view schematically illustrating a chassis and a circuit board in FIG. 1A;

FIG. 3 is a sectional view schematically illustrating the structure of a current sensor according to a variation in the first embodiment;

FIG. 4 is a sectional view schematically illustrating the structure of a current sensor according to another variation in the first embodiment:

FIG. 5A is a perspective view illustrating an example of a positional relationship between the chassis and externally connected portions of the bus bar;

FIG. 5B is a perspective view illustrating another example of a positional relationship between the chassis and the externally connected portions of the bus bar;

FIG. 6A is a sectional view schematically illustrating the structure of a current sensor according to a second embodiment;

FIG. 6B is a perspective view schematically illustrating the shape of a bus bar of the current sensor in FIG. 6A;

FIG. 6C is a sectional view schematically illustrating a cross section of the bus bar as taken along line VIC-VIC in FIG. 6B;

FIG. 7A is a sectional view schematically illustrating the structure of a current sensor according to a variation in the second embodiment;

FIG. 7B is a perspective view schematically illustrating the shape of the bus bar of the current sensor in FIG. 7A;

FIG. 7C is a sectional view schematically illustrating a cross section of the bus bar as taken along line VIIC-VIIC in FIG. 7B;

FIG. 8A is a perspective view schematically illustrating the structure of a bus bar of a current sensor according to another variation in the second embodiment;

FIG. 8B is a sectional view schematically illustrating a cross section of the bus bar as taken along line VIIIB-VIIIB in FIG. 8A;

FIG. 8C is a perspective view schematically illustrating an example of a shape that the bus bar in FIG. 8A can take before sheet-metal working;

FIG. 9A is a perspective view schematically illustrating the shape of a bus bar according to yet another variation in the second embodiment;

FIG. 9B is a sectional view schematically illustrating a cross section of the bus bar as taken along line IXB-IXB in FIG. 9A;

FIG. 10A is a sectional view schematically illustrating the structure of a current sensor according to still another variation in the second embodiment;

FIG. 10B is a perspective view schematically illustrating the shape of a bus bar in FIG. 10A;

FIG. 10C is a sectional view schematically illustrating a cross section of the bus bar as taken along line XC-XC in FIG. 10B;

FIG. 11 is a sectional view schematically illustrating the structure of a current sensor according to a third embodiment;

FIG. 12 is a plan view schematically illustrating an example of a positional relationship between a bus bar and a fixing terminal;

FIG. 13A is a plan view illustrating another example of a positional relationship between the bus bar and the fixing terminal;

FIG. 13B is a sectional view taken along line XIIIB-XIIIB in FIG. 13A;

FIG. 14 is a sectional view schematically illustrating the structure of a conventional current sensor;

FIG. 15A a perspective view schematically illustrating the shape of a bus bar of the conventional current sensor; and

FIG. 15B is a sectional view schematically illustrating a cross section of the bus bar as taken along line XVB-XVB in FIG. 15A.

### DESCRIPTION OF THE PREFERRED EMBODIMENTS

Embodiments of the present invention will be described below with reference to the attached drawings. Identical members will be assigned identical reference characters in the drawings, and repeated descriptions will be omitted. A reference coordinate system is appropriately indicated in each drawing to indicate a positional relationship among members. In the reference coordinate system, a direction in which both ends of a bus bar are linked on a circuit board will be taken as the X direction, a direction orthogonal to the X direction on the circuit board will be taken as the Y direction, and a direction orthogonal to the X direction and Y direction will be taken as the Z direction (a first direction or the normal direction of the circuit board). In the description below, the Z1-Z2 direction (Z direction) will be referred to as the up-down direction (height direction). The X1-X2 direction (X direction) and Y1-Y2 direction (Y direction) are orthogonal to each other. The Z1-Z2 direction (Z direction) is perpendicular to an XY plane. A state in which the upper side (the Z2 side in the Z direction) is viewed from the lower side (the Z1 side in the Z direction) will also be referred to as a plan view.

### First Embodiment

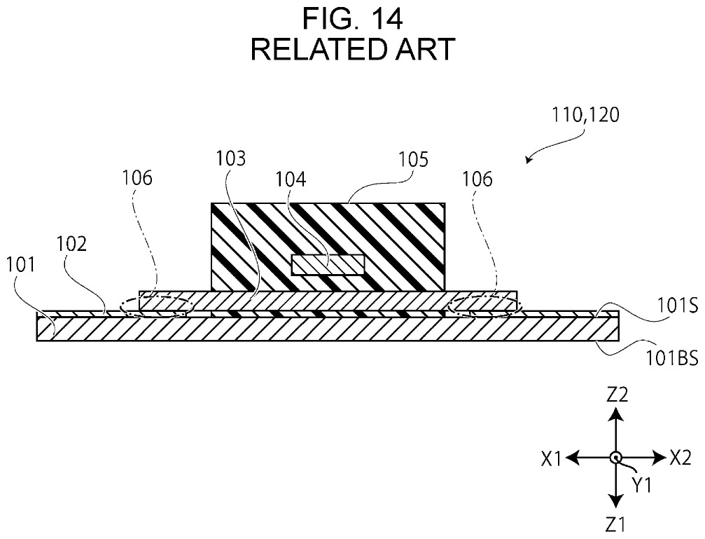

FIG. 14 is a sectional view schematically illustrating the structure of a current sensor 110 and current measurement device 120 in related art. With the current measurement device 120 in related art, which has the current sensor 110 as well as a circuit board 101 with current paths 102 provided on a mounting surface 101S, the current sensor 110 is disposed on the mounting surface 101S of the circuit board 101, as illustrated in the drawing. At a joining portion 106, a bus bar 103 and the relevant current path 102, which are included in current sensor 110, are fastened together. Solder or the like, for example, is used to form the joining portion 106.

When a current under measurement flows through the bus bar 103 in the current sensor 110, heat is generated at the joining portion 106 between the bus bar 103 and the current path 102. The amount of the heat is large and this generated heat causes a rise of the temperature of the current sensor 110. Thus, when the same side as the mounting surface 101S of the circuit board 101 and the same side as its back surface 101BS are compared with each other, the same side as the mounting surface 101S, on which a large heat source is present, becomes relatively hot and the back surface 101BS on the opposite side becomes relatively cool.

A chassis 105 of the current sensor 110 is a resin package that encloses bus bars 103, through which a current under measurement flows, a magnetism detection element 104 that senses the current under measurement in the bus bars 103, and the like. The chassis 105 is disposed on the same side as the mounting surface 101S. Thus, when a current flows through the bus bars 103, the current sensor 110 receives the effect of heat from the joining portions 106, which are heat sources, and is likely to become hot.

A thick-copper circuit board on which a current path made of copper is formed with the thickness of the copper being 140 μm or more may be used as a circuit board on which a current sensor of board-mounted type is to be mounted. A thick-copper circuit board of this type is more often used to have a large current flow than a circuit board on which the thickness of the copper of a current path is less than 140 μm. Therefore, when a large current flows through the current path on the thick-copper circuit board, a large amount of heat is generated in the current path and the same side as the mounting surface of the circuit board is likely to become hotter than when a circuit board is used on which the thickness of the copper of the current path, through which a relatively small current is flowed, is less than 140 μm. When the magnetism detection element 104 becomes a high temperature higher than or equal to heat-resistant temperature, current sensing precision of the current sensor is lowered. In view of this, a technology for efficiently cooling a current sensor of board-mounted type is demanded.

A structure by which the present invention efficiently cools a current sensor of board-mounted type will be described below.

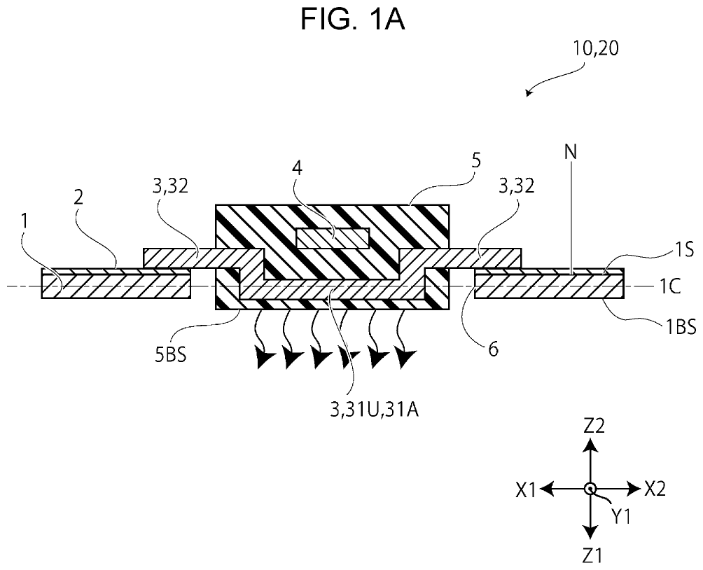

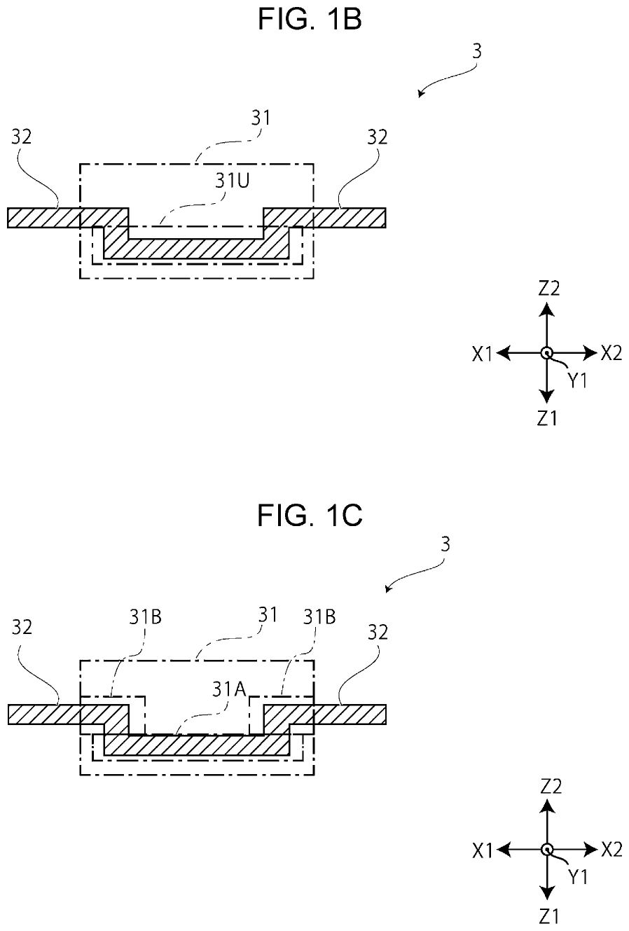

FIG. 1A is a sectional view schematically illustrating the structure of a current sensor 10 and current measurement device 20 according to this embodiment. As illustrated in the drawing, the current measurement device 20 has a circuit board 1 formed from an epoxy glass material, a ceramic material, or the like as well as a current sensor 10 having a bus bar 3, a magnetism detection element 4, and a chassis 5. FIG. 1A and the following drawings schematically indicate constituent elements to explain the structures of the present invention. The other constituent elements are not illustrated.

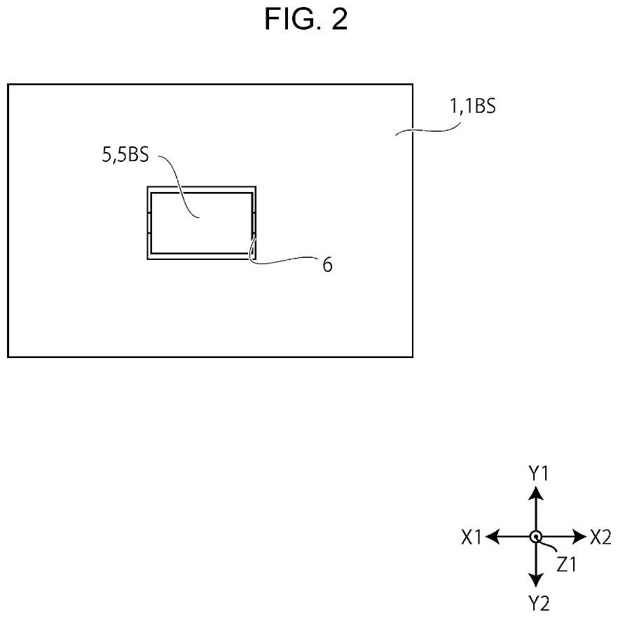

FIG. 2 is a plan view schematically illustrating the circuit board 1 and the chassis 5 of the current sensor 10 in FIG. 1A.

The circuit board 1 has an opening 6. In the example in FIG. 2, the opening 6 in a rectangular shape in plan view is formed so as to extend through the circuit board 1 in the thickness direction (Z direction).

The circuit board 1 has a mounting surface 1S, a normal N of which is the Z direction (a first direction). On the mounting surface 1S, current paths 2 are formed on both sides in the X direction, one on each side, with the opening 6 intervening between them. The current paths 2 are connected to the bus bar 3 by, for example, being soldered.

The current sensor 10 is mounted on the circuit board 1 in a state in which the chassis 5 is inserted into the opening 6 formed in the circuit board 1 and the bus bar 3 is connected to the current paths 2.

FIGS. 1B and 1C are each a sectional view schematically illustrating the structure of the bus bar 3 in FIG. 1A.

The bus bar 3 has an incorporation portion 31 placed in the interior of the chassis 5 as well as externally connected portions 32 extending toward the outside of the chassis 5 from both sides of the incorporation portion 31, one from each side, in the X direction.

In the present invention, in the Z direction, the Z2 side, on which the mounting surface 1S is disposed, is the upper side, and the Z1 side, on which a back surface 1BS is present, the Z1 side being opposite to the Z2 side, is the lower side, with reference to a center 1C of the circuit board 1 in the Z direction. Each externally connected portion 32 is positioned above a bottom surface 5BS of the chassis 5 in the Z direction, and is electrically connected to the relevant current path 2 disposed on the mounting surface 1S.

The incorporation portion 31 has an underneath portion 31U positioned below the externally connected portions 32 in the Z direction. The bottom surface 5BS of the chassis 5 may be positioned below the back surface 1BS of the circuit board 1. The bottom surface 5BS protrudes from the back surface 1BS of the circuit board 1.

Due to the underneath portion 31U, the incorporation portion 31 of the bus bar 3 can be distanced from the mounting surface 1S, which becomes a large heat source, toward the back surface 1BS, the temperature of which is relatively low. Therefore, it becomes possible to efficiently dissipate heat from the back surface 1BS, the temperature of which is relatively low, on the opposite side of the mounting surface 1S, on which the current paths 2 are formed, so the cooling efficiency of the current sensor 10 is improved.

The incorporation portion 31 may have a bottom portion 31A extending along the bottom surface 5BS of the chassis 5, and may also have linking portions 31B that extend upward from both ends of the bottom portion 31A, one from each side, in the X direction and are connected to the externally connected portions 32. Due to the bottom portion 31A in the incorporation portion 31, it becomes easy to dissipate heat of the bus bar 3 from the bottom surface 5BS of the chassis 5, so the cooling efficiency of the bus bar 3 is improved.

In a state in which the bottom portion 31A extends along the bottom surface 5BS of the chassis 5, the bottom portion 31A is laid so as to be substantially in parallel to the bottom surface 5BS on the lower side of the magnetism detection element 4 in the chassis 5.

The magnetism detection element 4 senses a current under measurement that flows through the bus bar 3. For example, a hall element, a magnetoresistance effect element, or the like is used as the magnetism detection element 4. The current sensor 10 uses the magnetism detection element 4 to sense a change in a magnetic field generated when a current under measurement flows through the bus bar 3, and measures the current flowing through the bus bar 3. In this embodiment, a structure in which a magnetoresistance effect element is used as the magnetism detection element 4 is illustrated. In this structure, the magnetoresistance effect element is placed so that a magnetic component in the Y direction can be sensed.

The magnetism detection element 4 may be placed at a position, on the Z2 side of the bus bar 3 in the Z direction, at which the magnetism detection element 4 faces the bottom portion 31A. Since the magnetism detection element 4 is positioned so as to face the bottom portion 31A, the temperature of the magnetism detection element 4 can be kept low and a drop in measurement precision of the current sensor 10 due to a temperature rise can be reduced.

### Variations

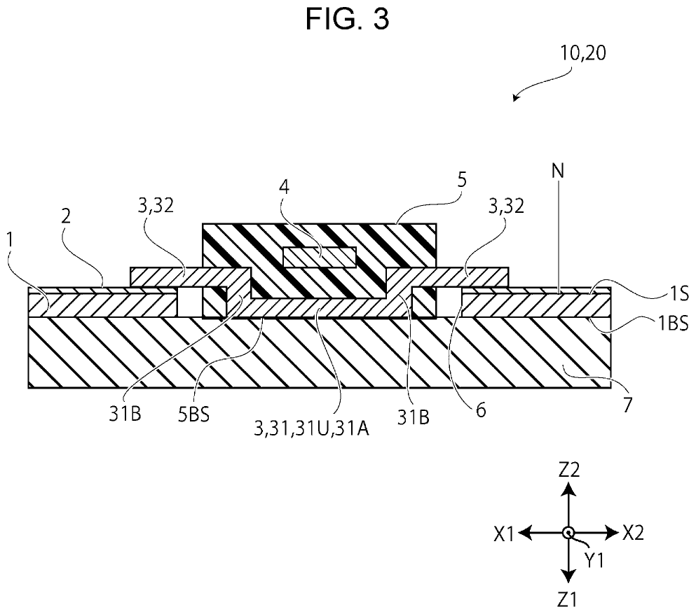

FIG. 3 is a sectional view schematically illustrating the structure of the current sensor 10 and current measurement device 20 according to a variation. In an embodiment of the current sensor 10 and current measurement device 20 illustrated in the drawing, the bottom surface 5BS of the chassis 5 is formed so as to be flush with the back surface 1BS of the circuit board 1 and is in contact with a heat dissipating member 7. Since the heat dissipating member 7 is in contact with the bottom surface 5BS of the chassis 5, it is possible to further enhance the heat dissipation efficiency.

A plate-like member (heat dissipating plate), a heat dissipating sheet in a sheet shape, or the like can be used as the heat dissipating member 7. The heat dissipating member 7 may be shaped so that the Z2 side in contact with the bottom surface 5BS of the chassis 5 is a flat surface and the Z1 side opposite to the Z2 side has high heat exchange efficiency. Examples of the heat dissipating sheet include an epoxy resin material to which a filler with superior thermal conductivity is added. A shape with high heat exchange efficiency is, for example, a shape including a plurality of protrusions.

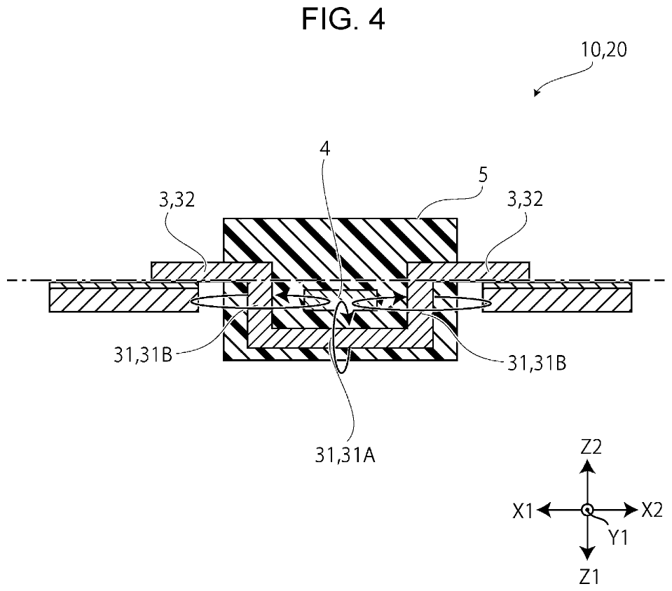

FIG. 4 is a sectional view schematically illustrating the structure of the current sensor 10 and current measurement device 20 according to another variation. In an embodiment of the current sensor 10 and current measurement device 20 illustrated in the drawing, the magnetism detection element 4 may be placed below the externally connected portions 32 in the interior of the chassis 5. The temperature of an area below the externally connected portion 32 is lower than the temperature of an area above the externally connected portion 32. In this structure, therefore, a rise in the temperature of the magnetism detection element 4 can be suppressed when a current under measurement flows through the bus bar 3. Therefore, the risk that the magnetism detection element 4 becomes hot due to heat generated from the bus bar 3 when a current under measurement flows and the durable temperature of the magnetism detection element 4 is thereby exceeded can be suppressed to a low level.

Since the magnetism detection element 4 is placed below the externally connected portions 32, when a current under measurement flows, not only an induced magnetic field from the bottom portion 31A of the incorporation portion 31 in the bus bar 3 but also an induced magnetic field from the linking portions 31B can be detected by the magnetism detection element 4. This improves the signal-to-noise (S/N) ratio of the magnetism detection element 4, so the sensing precision of the current sensor 10 becomes high.

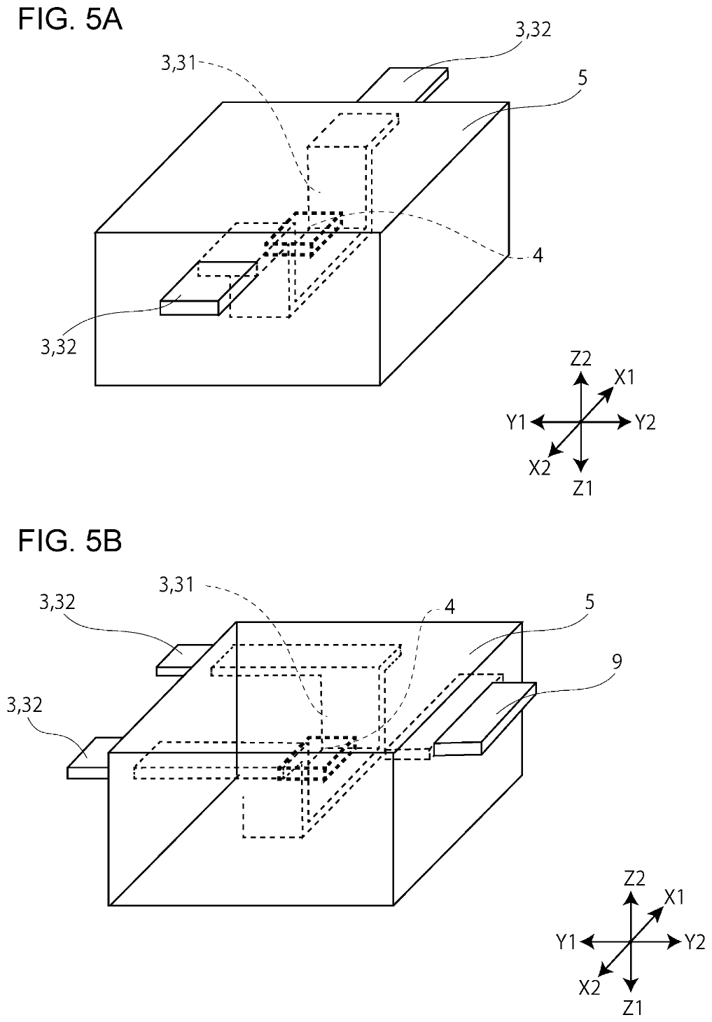

FIGS. 5A and 5B are each a perspective view illustrating examples of a positional relationship between the chassis 5 and the externally connected portions 32 of the bus bar 3. The externally connected portions 32 of the bus bar 3 may protrude from positions on the opposing sides of the chassis 5 as illustrated in FIG. 5A (in the drawing, on the X1 side and X2 side in the X direction) or from positions on the same side of the chassis 5 as illustrated in FIG. 5B (in the drawing, on the Y1 side in the Y direction), when viewed from the Z direction.

In FIG. 5B, both ends (externally connected portions 32) of the bus bar 3 protrude toward the Y1 side of the chassis 5. When the current sensor 10 having the structure in FIG. 5B is placed with the chassis 5 inserted into the opening 6 in the circuit board 1, only the Y1 side of the current sensor 10 is held to the circuit board 1 (see FIGS. 1A and 2). When vibration is added in this state, the chassis 5 swings in the up-down direction (Z direction) with portions, fixed to the circuit board 1, of the externally connected portions 32 acting as fulcrums. This causes a fear such that the fixed portions are damaged. To prevent this, a fixing terminal 9 that fixes the current sensor 10 is provided to stably support the structural portion of the current sensor 10, the portion receiving a load from the outside. The fixing terminal 9 is fixed to the circuit board 1 at a portion other than the Y1 side, from which the externally connected portions 32 protrude, of the chassis 5. Therefore, it becomes possible to stably hold the current sensor 10 to the circuit board 1. The fixing terminal 9 is, for example, a soldered terminal or the like. The fixing terminal 9 may be used as a ground terminal.

As described above, the current sensor 10 and current measurement device 20 in this embodiment have the underneath portion 31U in which the incorporation portion 31 of the bus bar 3 is positioned below the externally connected portions 32. In this structure, a rise in the temperature of the magnetism detection element 4 can be reduced with the suppression of the effect of heat generation that occurs at the mounting surface 1S of the circuit board 1 when a current under measurement flows through the bus bar 3.

### Second Embodiment

In this embodiment, an aspect will be described in which the bus bar 3 has a narrow portion 3N at a place at which the narrow portion 3N faces the magnetism detection element 4 to improve frequency characteristics due to a skin effect.

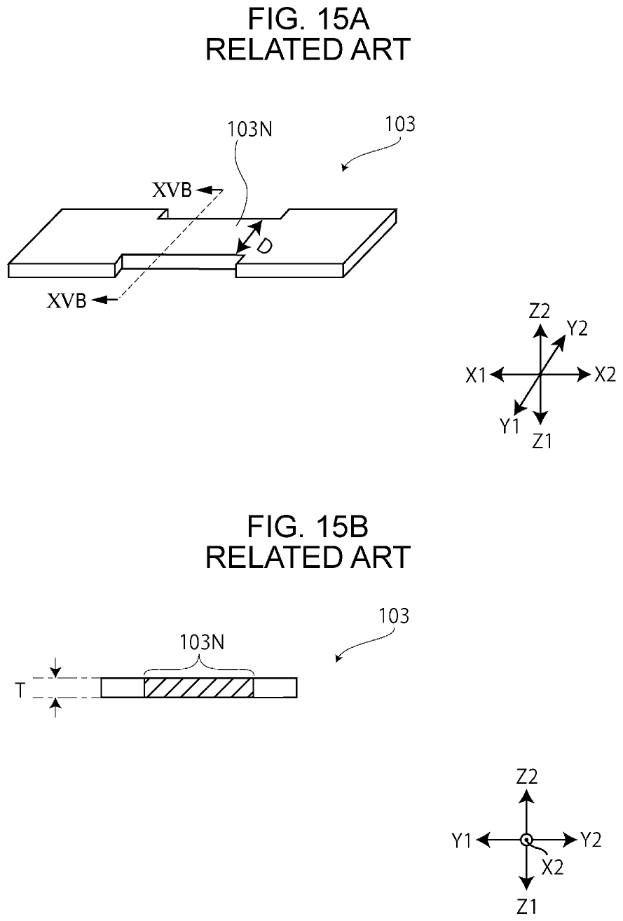

FIG. 15A a perspective view schematically illustrating the shape of the bus bar 103 of the current sensor 110 (see FIG. 14) in related art, and FIG. 15B is a sectional view schematically illustrating a cross section of the bus bar 103 as taken along line XVB-XVB in FIG. 15A.

As illustrated in these drawings, a narrow portion 103N of the bus bar 103 in related art is such that a width D in the direction (Y direction) orthogonal to the extending direction (X direction) of the bus bar 103 is narrower than the widths of other portions and that a thickness T in the up-down direction (Z direction) is the same as the thicknesses of the other portions. Thus, the cross-sectional area of the narrow portion 103N cut along a YZ plane is smaller than the cross-sectional areas of the other portions of the bus bar 103, so the electric resistance at the narrow portion 103N is large. This is problematic in that when a current under measurement flows through the bus bar 103, the narrow portion 103N is likely to generate heat and the temperature of the magnetism detection element 104 thereby becomes high due to heat generated at the narrow portion 103N.

In view of this, the bus bar of the current sensor and current measurement device in this embodiment has a structure in which a thick portion is provided at the narrow portion so that part of the bus bar protrudes. In this structure, the cross-sectional area of the narrow portion, for example, can be made substantially equal to or greater than the cross-sectional areas of other portions. Thus, the electric resistance at the narrow portion becomes small, so it becomes possible to reduce heat generated at the narrow portion when a current under measurement flows.

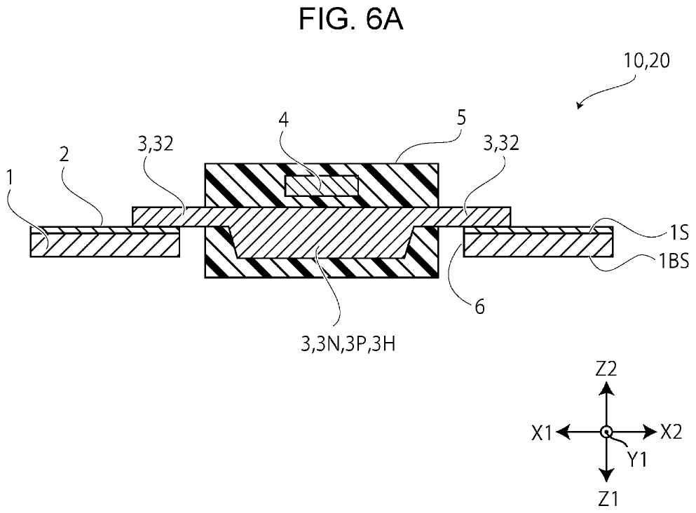

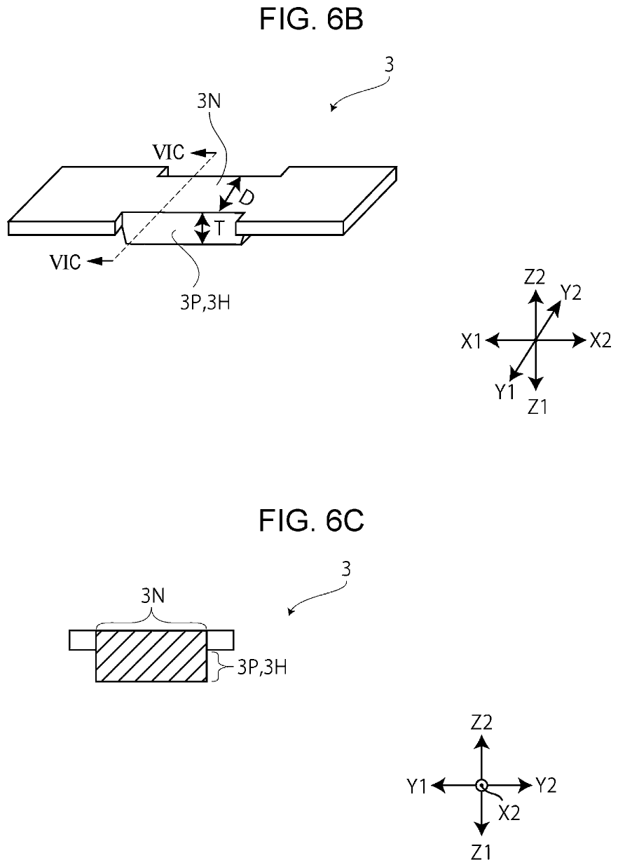

FIG. 6A is a sectional view schematically illustrating the structure of the current sensor 10 and current measurement device 20 according to this embodiment. FIG. 6B is a perspective view schematically illustrating the shape of the bus bar 3 in FIG. 6A. FIG. 6C is a sectional view schematically illustrating a cross section of the bus bar 3 as taken along line VIC-VIC in FIG. 6B.

As illustrated in these drawings, the narrow portion 3N of the bus bar 3 may be formed so that the width D in the direction (Y direction) orthogonal to the extending direction (X direction) of the bus bar 3 is smaller (thinner) than the widths of other portions when viewed from the Z direction. The narrow portion 3N may have a thick portion 3P with the thickness T, in the up-down direction (Z direction), the thickness T being greater than the thicknesses of the other portions when viewed from the X direction. Thus, when the width D of the narrow portion 3N in the Y direction and the thickness T of the thick portion 3P in the Z direction are adjusted, the cross-sectional area of the narrow portion 3N, for example, can be made substantially equal to the cross-sectional areas of both ends of the narrow portion 3N in the X direction. Therefore, the electric resistance at the narrow portion 3N of the bus bar 3 can be made substantially equal to the electric resistances of the other portions and heat generated at the narrow portion 3N can be reduced when a current under measurement flows.

A current under measurement in the bus bar 3 flows along the X direction. Thus, when the upper side of the bus bar 3 is formed as a flat surface, the magnetic field to be measured by the magnetism detection element 4 does not greatly change in spite of the thick portion 3P being provided at the narrow portion 3N. At the same time, since heat highly evenly propagates at the narrow portion 3N of the bus bar 3, the thick portion 3P of the narrow portion 3N functions as a heat sink that promotes heat dissipation from the bus bar 3.

Therefore, when the thick portion 3P is provided, the efficiency of heat dissipation from the thick portion 3P is improved. When the thick portion 3P is disposed below the externally connected portions 32, the effect of heat generated from the externally connected portions 32 can be reduced. Therefore, when the thick portion 3P, which functions as a heat dissipating portion 3H, is provided, a rise in the temperature of the magnetism detection element 4 due to heat generated at the narrow portion 3N can be suppressed.

### Variations

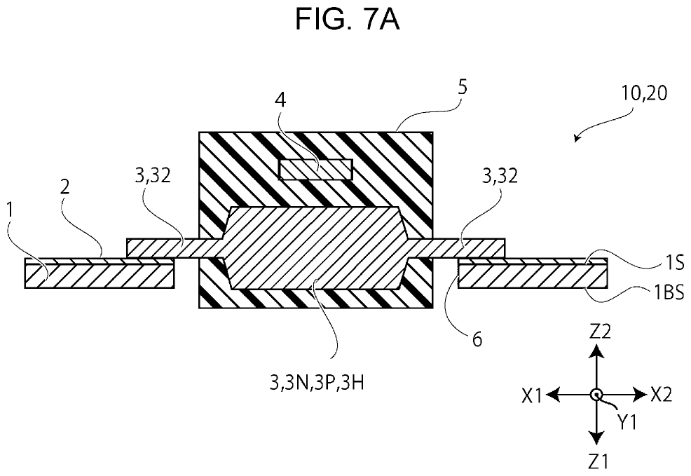

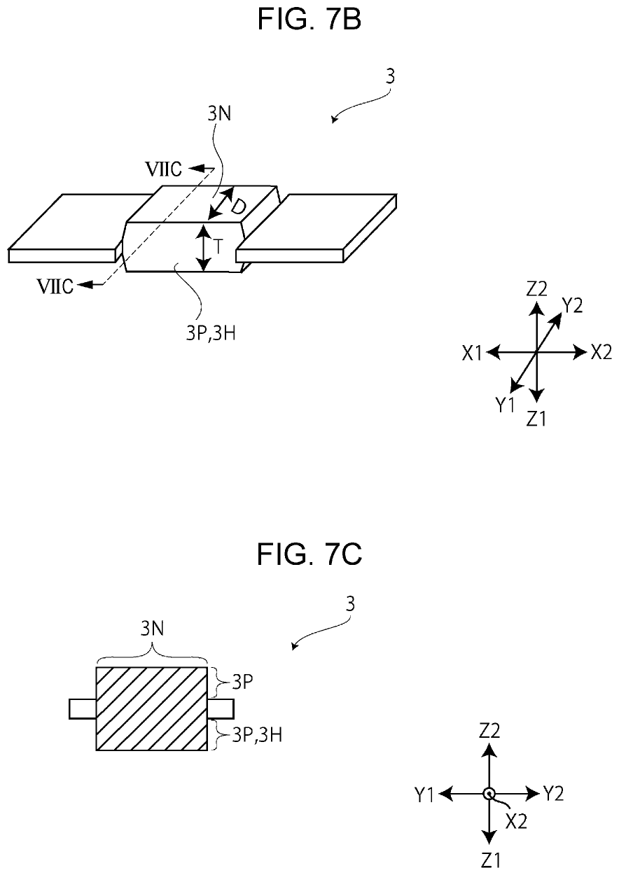

FIG. 7A is a sectional view schematically illustrating the structure of the current sensor 10 and current measurement device 20 according to a variation. FIG. 7B is a perspective view schematically illustrating the shape of the bus bar 3 of the current sensor 10 in FIG. 7A. FIG. 7C is a sectional view schematically illustrating a cross section of the bus bar 3 as taken along line VIIC-VIIC in FIG. 7B.

In an embodiment of the current sensor 10 illustrated in these drawings, the thick portion 3P has not only the heat dissipating portion 3H but also a portion protruding above the externally connected portions 32. At the portion, protruding upward, of the thick portion 3P, the effect of dissipating heat of the bus bar 3 to the outside is smaller than the effect at a portion protruding downward. However, when the cross-sectional area of the narrow portion 3N is enlarged, the electric resistance of the bus bar 3 can be lowered.

The thick portion 3P, illustrated in FIGS. 6A to 6C and FIGS. 7A to 7C, of the narrow portion 3N can be formed by, for example, pressing a portion to be formed as the narrow portion 3N, the portion being part of a metal plate extending in the X direction, from both sides in the Y direction to bend, in the Z direction, the metal that was present at the portion before its width has been narrowed.

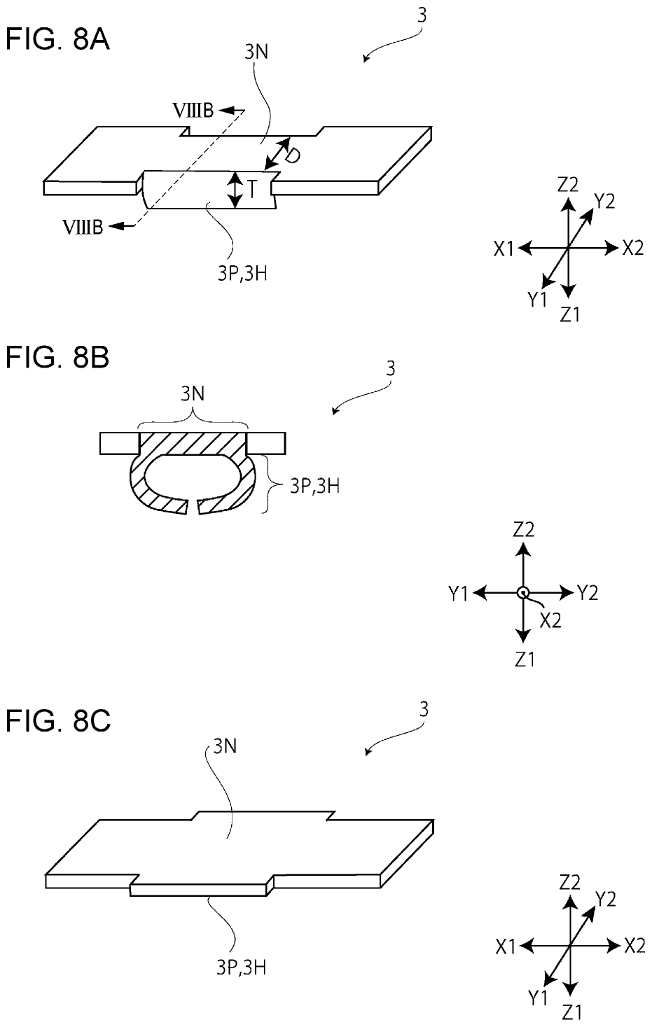

FIG. 8A is a perspective view schematically illustrating the structure of the bus bar 3 according to another variation. FIG. 8B is a sectional view schematically illustrating a cross section of the bus bar 3 as taken along line VIIIB-VIIIB in FIG. 8A.

As illustrated in these drawings, when a portion to be formed as the narrow portion 3N is rounded downward by sheet metal processing, the portion being part of a metal plate extending in the X direction, the narrow portion 3N having the thick portion 3P, which functions as the heat dissipating portion 3H, can be formed.

FIG. 8C is a perspective view schematically illustrating an example of a shape that the bus bar 3 in FIG. 8A can take before sheet-metal working. As illustrated in the drawing, a base material before sheet metal processing may have been formed so that both sides, in the Y direction, of a portion to be formed as the narrow portion 3N protrude when the base material is viewed from the Z direction. In other words, the base material may have been formed in a cross shape. When a cut is made in part of the base material formed like this and the relevant portion is rounded to form the narrow portion 3N, the shape of the thick portion 3P can be enlarged to improve the function of the heat dissipating portion 3H.

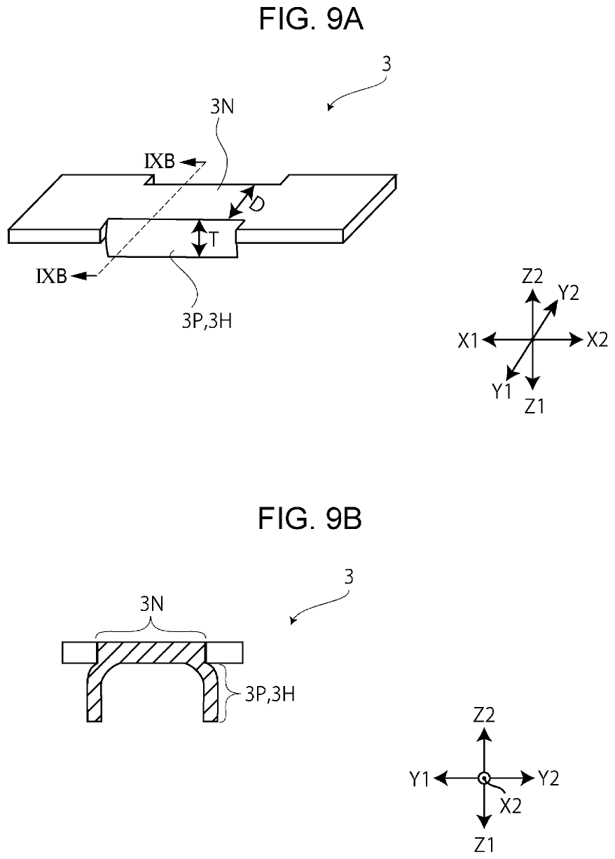

FIG. 9A is a perspective view schematically illustrating the shape of the bus bar 3 according to yet another variation. FIG. 9B is a sectional view schematically illustrating a cross section of the bus bar 3 as taken along line IXB-IXB in FIG. 9A.

As illustrated in these drawings, when part of the bus bar 3 is bent downward from both sides in the Y direction, the narrow portion 3N, which has the thick portion 3P that functions as the heat dissipating portion 3H, can be formed.

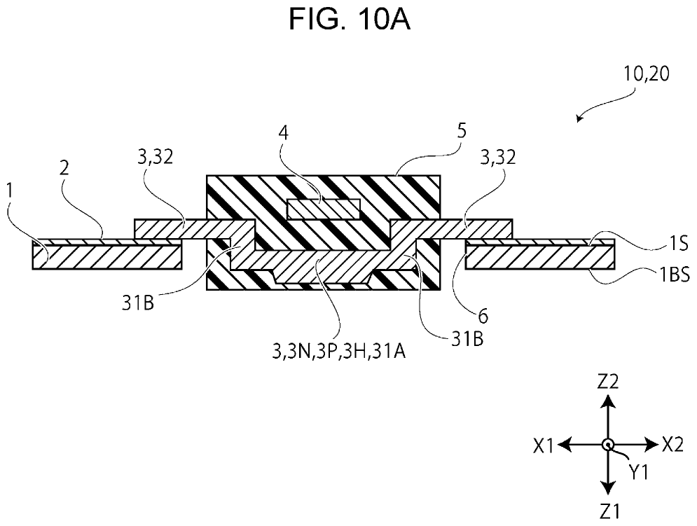

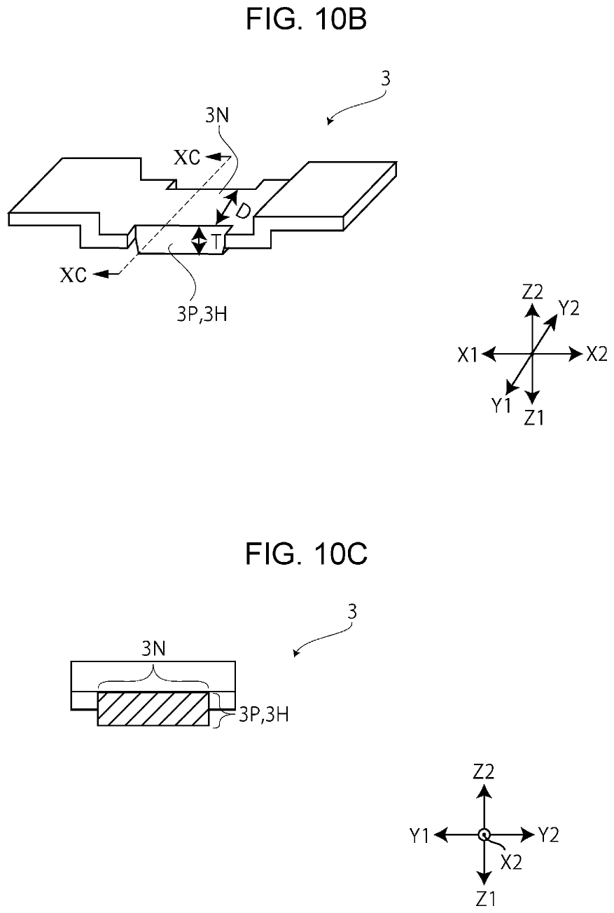

FIG. 10A is a sectional view schematically illustrating the structure of the current sensor 10 according to still another variation. FIG. 10B is a perspective view schematically illustrating the shape of the bus bar 3 in FIG. 10A. FIG. 10C is a sectional view schematically illustrating a cross section of the bus bar 3 as taken along line XC-XC in FIG. 10B.

As illustrated in these drawings, the narrow portion 3N may be formed at the bottom portion 31A of the bus bar 3, which has the bottom portion 31A and linking portions 31B. The bus bar 3 may also be structured so that the whole of the narrow portion 3N is positioned below the externally connected portions 32.

As described above, with the current sensor 10 and current measurement device 20 in this embodiment, the narrow portion 3N of the bus bar 3 has the thick portion 3P that functions as the heat dissipating portion 3H, so when a current under measurement flows through the bus bar 3, heat generated at the narrow portion 3N can be reduced. Therefore, since a rise in the temperature of the magnetism detection element 4 due to heat generated by the bus bar 3 is reduced, measurement precision of the current sensor 10 can be enhanced.

### Third Embodiment

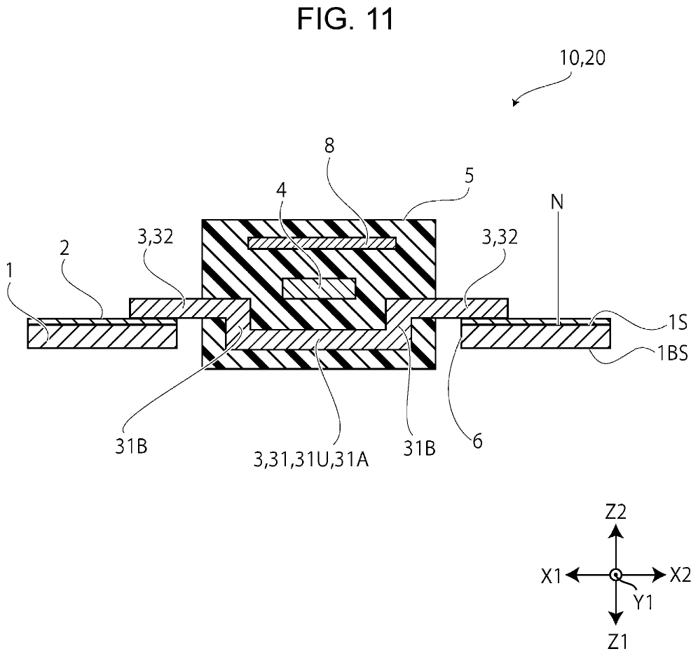

FIG. 11 is a sectional view schematically illustrating the structure of the current sensor 10 and current measurement device 20 according to this embodiment. As illustrated in the drawing, the current sensor 10 and current measurement device 20 may have a magnetic shield 8 at a position above the magnetism detection element 4.

Since the magnetic shield 8 is provided, magnetic noise from the outside is reduced, so measurement precision of the current sensor 10 is improved. An example of the magnetic shield 8 is a stack of a plurality of metallic plate-like bodies having the same shape. A U-type magnetic shield, the cross section of which is U-shaped, may be used instead of the flat-plate-type magnetic shield illustrated in FIG. 11. The current sensor 10 and current measurement device 20 may also be structured so that magnetic shields are provided above and below the bus bar 3 or a magnetic shield is provided only below the bus bar 3.

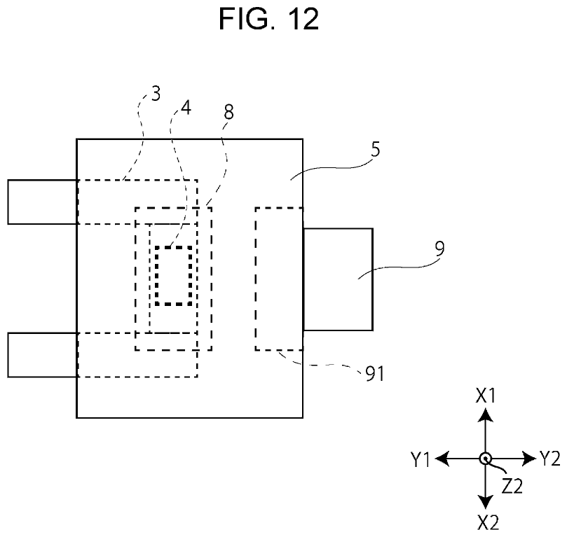

FIG. 12 is a plan view illustrating an example of the current sensor 10 that has a fixing terminal 9. In this embodiment, the fixing terminal 9 is provided so as to protrude toward the Y2 side of the chassis 5. However, the current sensor 10 may be structured so that the fixing terminal 9 is provided so as to protrude toward both sides of the chassis 5 in the X direction. The fixing terminal 9 and the externally connected portions 32 of the bus bar 3 protrude at the same position in the Z direction (at positions at the same height) when the current sensor 10 is viewed along the X direction (see FIG. 5B).

A member forming the fixing terminal 9 has a buried portion 91, which is buried in the chassis 5. Since the fixing terminal 9 is just schematically illustrated in FIG. 12, the end of the buried portion 91 on the Y2 side is drawn so as to be exploded to a side surface of the chassis 5. However, when the buried portion 91 is exposed, the fixing terminal 9 is likely to drop from the chassis 5. Preferably, therefore, the buried portion 91 is not exposed to the outside of the chassis 5.

In the plan view in FIG. 12, an example of a positional relationship between the bus bar 3 and the fixing terminal 9 is also schematically illustrated. As illustrated in the drawing, the magnetic shield 8 may be provided separately from the fixing terminal 9, which fixes the current sensor 10.

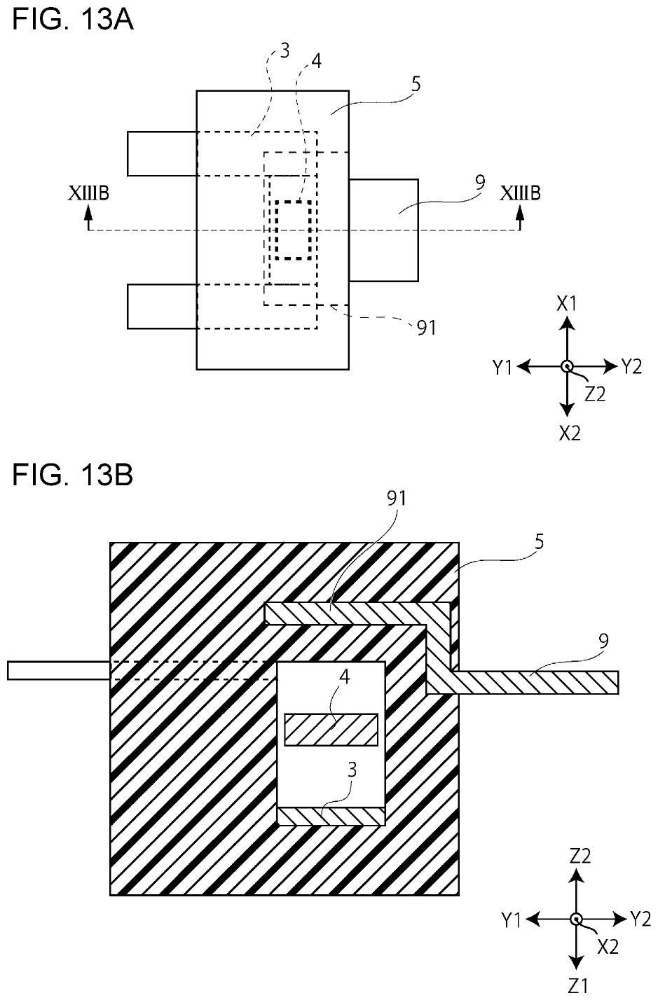

FIG. 13A is a plan view illustrating another example of a positional relationship between the bus bar 3 and the fixing terminal 9. FIG. 13B is a sectional view taken along line XIIIB-XIIIB in FIG. 13A.

As illustrated in FIG. 13A, part of the buried portion 91 of the fixing terminal 9 may overlap part of the magnetism detection element 4 and part of the bus bar 3 when viewed from the Z direction.

The buried portion 91 of the fixing terminal 9 extending in the Y direction is bent in a crank shape when viewed from the X direction and is routed to a position at which the buried portion 91 overlaps part of the magnetism detection element 4 and part of the bus bar 3 when viewed from the Z direction, as illustrated in FIG. 13B. In this case, when the fixing terminal 9 is manufactured from the same material as the magnetic shield 8 and is then plated so that the magnetic shield 8 can be soldered, the fixing terminal 9 can have a magnetic shield function. In this structure, magnetic noise can be reduced and the buried portion 91 can be placed at the position at which the magnetic shield 8 is placed. Therefore, it is possible to downsize the current sensor 10. An embodiment in which the fixing terminal 9 has a magnetic shield function has been described with reference to FIGS. 13A and 13B. However, the fixing terminal 9 may have only the shape and placement structure illustrated in these drawings without having a magnetic shield function.

The embodiments disclosed in this description are exemplary in all points. The present invention is not restricted to these embodiments. The scope of the present invention is not indicated by the description of only the embodiments described above but is indicated by the scope of the claims. It is intended that meanings equivalent to the scope of the claims and all modifications in the scope are included.

The present invention is useful as a current sensor and a current measurement device that are attached to any type of unit and measure a current under measurement to control and monitor the unit.

What is claimed is:

1. A current sensor comprising:
a bus bar through which a current under measurement flows;
a magnetism detection element; and
a chassis; wherein
the current sensor is mounted on a circuit board in a state in which the chassis is inserted into an opening formed in the circuit board with a current path being provided on a mounting surface and the bus bar is connected to the current path,
the bus bar has an incorporation portion placed in an interior of the chassis as well as externally connected portions extending from both ends of the incorporation portion, one from each side, toward an outside of the chassis, and
when, in a first direction, which is a normal direction of the circuit board, a side on which the mounting surface is positioned is taken as an upper side and a side opposite to the upper side is taken as a lower side with respect to a center of the circuit board in the first direction,
the externally connected portions are positioned above a bottom surface of the chassis in the first direction, and
the incorporation portion has an underneath portion positioned below the externally connected portions in the first direction.

2. The current sensor according to claim 1, wherein the bottom surface of the chassis is positioned below a back surface, which is a lower surface of the circuit board.

3. The current sensor according to claim 1, wherein the underneath portion has a portion positioned below a back surface, which is a lower surface of the circuit board.

4. The current sensor according to claim 1, wherein the underneath portion has
a bottom portion extending along the bottom surface of the chassis, and
linking portions that extend upward from both ends of the bottom portion, one from each side, and each of which is connected to one of the externally connected portions.

5. The current sensor according to claim 4, wherein the magnetism detection element is placed at a position, in the interior of the chassis, at which the magnetism detection element faces the bottom portion in the first direction.

6. The current sensor according to claim 4, wherein the magnetism detection element is placed, in the interior of the chassis, below the externally connected portions in the first direction.

7. The current sensor according to claim 1, wherein the incorporation portion has a thick portion, a thickness of which is greater than a thickness of another portion in the first direction, at a narrow portion, a width of which is smaller than a width of the another portion when viewed from the first direction.

8. The current sensor according to claim 7, wherein the thick portion has a heat dissipating portion protruding downward beyond the externally connected portions.

9. The current sensor according to claim 1, further comprising a magnetic shield.

10. A current measurement device comprising:
the current sensor according to claim 1; and
the circuit board with the current path provided on the mounting surface.
